(19) United States
(12) Patent Application Publication
(10) Pub. No.: US 2012/0104487 A1
(43) Pub. Date: May 3, 2012

(54) SEMICONDUCTOR DEVICE AND METHOD OF FORMING THE SAME

(75) Inventors: Yoshinori IKEBUCHI, Tokyo (JP); Yoshihiro TAKAISHI, Tokyo (JP)

(73) Assignee: ELPIDA MEMORY, INC., Tokyo (JP)

(21) Appl. No.: 13/281,471

(22) Filed: Oct. 26, 2011

(30) Foreign Application Priority Data
Oct. 28, 2010 (JP) 2010-242319

(51) Int. Cl. H01L 29/78

(52) U.S. Cl. 257/329; 257/E29.262

(57) ABSTRACT

A semiconductor device may include, but is not limited to, a transistor and a contact plug pillar of an impurity-diffused semiconductor. The transistor includes a semiconductor channel pillar having a vertical channel; and a first diffusion region adjacent to a lower portion of the semiconductor channel pillar. The contact plug pillar of an impurity-diffused semiconductor is coupled to the first diffusion region.

### BACKGROUND OF THE INVENTION

1. Field of the Invention

The present invention generally relates to a semiconductor device and a method of forming the same.

Priority is claimed on Japanese Patent Application No. 2010-242319, filed Oct. 28, 2010, the content of which is incorporated herein by reference.

2. Description of the Related Art

A conventional transistor suitable for achieving a high level of integration in a semiconductor device is a vertical transistor having a channel pillar in the form of a columnar semiconductor layer functioning as a channel, an upper diffusion layer connected to an upper part of the channel pillar and functioning as one of the source/drain, a lower diffusion layer connected to a lower part of the channel pillar and functioning as other of the source/drain, and a gate electrode disposed in opposition to a side surface of the channel pillar via a gate insulating film.

Japanese Patent Application Publication No. JPA 2009-81389 discloses that from the standpoint of reducing the surface area and improving the performance of the semiconductor device, a three-dimensional vertical all-around gate transistor has been proposed, in which the gate electrode is disposed so as to surround the entire side surface of a channel pillar that is made of a columnar semiconductor layer, interposing the gate insulating film therebetween.

In general, the upper diffusion layer, lower diffusion layer, and gate electrode of a vertical transistor are each electrically connected to an interconnect formed as the upper layer of the vertical transistor. Also, the interconnects formed on the lower diffusion layer and the upper layer of the vertical transistor are electrically connected using a lower diffusion layer lead contact plug formed on an insulating film. The lower diffusion layer lead contact plug is usually formed by a method of forming a deep contact hole in the insulating film, and then burying a conducting material within the deep contact hole.

In the case in which a lower diffusion layer lead contact plug is formed using such as method, in consideration of the positioning margin when forming the deep contact hole, it is necessary to establish a sufficient spacing between the channel pillar and the lower diffusion layer lead contact plug of the vertical transistor. For this reason, it was not possible to set the spacing between the channel pillar of the vertical transistor T and the lower diffusion layer lead contact plug to F (which is the minimum processing dimension).

Japanese Patent Application Publication No. JPA H6-268173 discloses the related art to use so that integration is not hindered by the surface area for the purpose of connecting the lower diffusion layer with the interconnects formed on the upper layer of the vertical transistor, whereby the vertical transistor is directly connected, in which an interconnect is not necessary that connects to a second source/drain diffusion layer formed on the surface of the lower side surface of the vertical MOS transistor. Because the channel length of the transistor is doubled, the transistor on-state current decreases, thereby deteriorating the characteristics of the vertical transistor.

### SUMMARY

In one embodiment, a semiconductor device may include, but is not limited to, a transistor and a contact plug pillar of an impurity-diffused semiconductor. The transistor may include, but is not limited to, a semiconductor channel pillar having a vertical channel; and a first diffusion region adjacent to a lower portion of the semiconductor channel pillar. The contact plug pillar of an impurity-diffused semiconductor is coupled to the first diffusion region.

In another embodiment, a semiconductor device may include, but is not limited to, a semiconductor substrate; a first semiconductor pillar extending from the substrate, the first semiconductor pillar being substantially the same in impurity concentration as the semiconductor substrate; and a second semiconductor pillar extending from the substrate. The second semiconductor pillar is spatially separated from the first semiconductor pillar. The second semiconductor pillar is higher in impurity concentration than the semiconductor substrate and the first semiconductor pillar.

In still another embodiment, a semiconductor device may include, but is not limited to, a semiconductor substrate; a semiconductor channel pillar having a vertical channel, the semiconductor channel pillar extending from the semiconductor substrate; a contact plug pillar extending from the semiconductor substrate, the contact plug pillar being spatially separated from the semiconductor channel pillar; a semiconductor diffusion region being higher in impurity concentration than the semiconductor substrate and the semiconductor channel pillar, the semiconductor diffusion region occupying the contact plug pillar and a shallow region of the semiconductor substrate, the shallow region being adjacent to a bottom of the semiconductor channel pillar. A gate electrode is disposed between the semiconductor channel pillar and the contact plug pillar. An insulating film is disposed between the semiconductor channel pillar and the contact plug pillar. The insulating film electrically insulates the gate electrode from the semiconductor channel pillar and from the contact plug pillar.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a fragmentary cross sectional elevation view of a semiconductor device in accordance with a first embodiment of the present invention;

FIG. 2 is a fragmentary plan view of the semiconductor device of FIG. 1 which is the view taken along an A-A′ line of FIG. 2;

FIG. 3 is a fragmentary cross sectional elevation view of a step involved in a method of forming the semiconductor device of FIGS. 1 and 2;

FIG. 4 is a fragmentary cross sectional elevation view of a step, subsequent to the step of FIG. 3, involved in a method of forming the semiconductor device of FIGS. 1 and 2;

FIG. 5 is a fragmentary cross sectional elevation view of a step, subsequent to the step of FIG. 4, involved in a method of forming the semiconductor device of FIGS. 1 and 2;

FIG. 6 is a fragmentary cross sectional elevation view of a step, subsequent to the step of FIG. 5, involved in a method of forming the semiconductor device of FIGS. 1 and 2;

FIG. 7 is a fragmentary cross sectional elevation view of a step, subsequent to the step of FIG. 6, involved in a method of forming the semiconductor device of FIGS. 1 and 2;

FIG. 8 is a fragmentary cross sectional elevation view of a step, subsequent to the step of FIG. 7, involved in a method of forming the semiconductor device of FIGS. 1 and 2;

FIG. 9 is a fragmentary cross sectional elevation view of a step, subsequent to the step of FIG. 8, involved in a method of forming the semiconductor device of FIGS. 1 and 2;

FIG. 10 is a fragmentary cross sectional elevation view of a step, subsequent to the step of FIG. 9, involved in a method of forming the semiconductor device of FIGS. 1 and 2; and

FIG. 11 is a fragmentary cross sectional elevation view of a step, subsequent to the step of FIG. 10, involved in a method of forming the semiconductor device of FIGS. 1 and 2.

### DETAILED DESCRIPTION OF THE PREFERRED EMBODIMENTS

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In one embodiment, a semiconductor device may include, but is not limited to, a transistor and a contact plug pillar of an impurity-diffused semiconductor. The transistor may include, but is not limited to, a semiconductor channel pillar having a vertical channel; and a first diffusion region adjacent to a lower portion of the semiconductor channel pillar. The contact plug pillar of an impurity-diffused semiconductor is coupled to the first diffusion region.

In some cases, the first diffusion region and the contact plug pillar are higher in impurity concentration than the semiconductor channel pillar.

In some cases, the vertical transistor further may include, but is not limited to, a second diffusion region disposed on a top of the semiconductor channel pillar.

In some cases, the vertical transistor further may include, but is not limited to, a gate insulating film covering a side wall surface of the semiconductor channel pillar; and a gate electrode on the gate insulating film. The gate electrode has a first side surface that faces toward the semiconductor channel pillar through the gate insulating film.

In some cases, the gate electrode is disposed at least a gap between the semiconductor channel pillar and the contact plug pillar.

In some cases, the gate electrode and the gate insulating film surround the semiconductor channel pillar and the gate electrode and the gate insulating film also surround the contact plug pillar.

In some cases, the gate electrode may include, but is not limited to, a tungsten film; and a titanium nitride film disposed between the tungsten film and the gate insulating film.

In some cases, the semiconductor device may include, but is not limited to, a first insulating film extending between the gate electrode and the contact plug pillar.

In some cases, the semiconductor device may include, but is not limited to, a top plug disposed on a top of the contact plug pillar. The top plug is made of a same material as the second diffusion region, the top plug being coupled to the contact plug pillar.

In some cases, the semiconductor device may include, but is not limited to, a first connection plug disposed on the second diffusion region; a second connection plug disposed on the top plug; a first interconnect coupled through the first connection plug to the second diffusion region; and a second interconnect coupled through the second connection plug to the top plug.

In some cases, the contact plug pillar is substantially the same in top level as the semiconductor channel pillar.

In some cases, the contact plug pillar and the semiconductor channel pillar are lower in top level than the gate electrode.

In some cases, the contact plug pillar has substantially the same in impurity concentration as the first diffusion region.

In some cases, the contact plug pillar and the semiconductor channel pillar are substantially the same horizontal dimensions as each other.

In another embodiment, a semiconductor device may include, but is not limited to, a semiconductor substrate; a first semiconductor pillar extending from the substrate, the first semiconductor pillar being substantially the same in impurity concentration as the semiconductor substrate; and a second semiconductor pillar extending from the substrate. The second semiconductor pillar is spatially separated from the first semiconductor pillar. The second semiconductor pillar is higher in impurity concentration than the semiconductor substrate and the first semiconductor pillar.

In some cases, the semiconductor device may include, but is not limited to, a bottom diffusion region in the semiconductor substrate. The bottom diffusion region is adjacent to a bottom of the first semiconductor pillar. The bottom diffusion region is coupled to the second semiconductor pillar. The second semiconductor pillar may include, but is not limited to, a diffusion region coupled to the bottom diffusion region.

In some cases, the semiconductor device may include, but is not limited to, a first top diffusion region on a top of the first semiconductor pillar; a gate insulating film covering side wall surfaces of the first semiconductor pillar; a gate electrode disposed in the gap between the first and second semiconductor pillars; and a first insulating film covering side wall surfaces of the second semiconductor pillar. The gate electrode is separated by the gate insulating film from the first semiconductor pillar, and the gate electrode is separated by the first insulating film from the second semiconductor pillar.

In some cases, the first and second semiconductor pillars have substantially the same height as each other. The first and second semiconductor pillars are lower in top level than the gate electrode.

In some cases, the semiconductor device may include, but is not limited to, a second top diffusion region on a top of the second semiconductor pillar, the second top diffusion region being made of a same material as the first top diffusion region, the second top diffusion region being coupled to the second semiconductor pillar; a first connection plug disposed on the first top diffusion region; a second connection plug disposed on the second top diffusion region; a first interconnect coupled through the first connection plug to the first top diffusion region; and a second interconnect coupled through the second connection plug to the second top diffusion region.

In still another embodiment, a semiconductor device may include, but is not limited to, a semiconductor substrate; a semiconductor channel pillar having a vertical channel, the semiconductor channel pillar extending from the semiconductor substrate; a contact plug pillar extending from the semiconductor substrate, the contact plug pillar being spatially separated from the semiconductor channel pillar; a semiconductor diffusion region being higher in impurity concentration than the semiconductor substrate and the semiconductor channel pillar, the semiconductor diffusion region occupying the contact plug pillar and a shallow region of the semiconductor substrate, the shallow region being adjacent to a bottom of the semiconductor channel pillar. A gate electrode is disposed between the semiconductor channel pillar and the contact plug pillar. An insulating film is disposed between the semiconductor channel pillar and the contact plug pillar. The insulating film electrically insulates the gate electrode from the semiconductor channel pillar and from the contact plug pillar.

In yet another embodiment, a method of forming a semiconductor device may include, but is not limited to, the following processes. A plurality of pillars is formed, which are spatially separated from each other. Bottom diffusion regions are formed, which are connected to bottoms of the pillars. The bottom diffusion regions are to perform as one of source and drain regions of vertical transistors. A first sub-plurality of pillars included in the plurality of pillars is made into channel pillars providing channels of the vertical transistors. An impurity is diffused into portions of a second sub-plurality of pillars included in the plurality of pillars into channel pillars to form contact plugs electrically coupled to the bottom diffusion layer.

In some cases, the method may include, but is not limited to, the following processes. Gate insulating films are formed on side walls of the first sub-plurality of pillars. Gate electrodes are formed on the gate insulating films. The gate electrodes are disposed in one side of the gate insulating films while the first sub-plurality of pillars being in the other side of the gate insulating films. Top diffusion layers are formed on the first sub-plurality of pillars. The top diffusion layers are to perform as the other of source and drain of the vertical transistor.

In some cases, the method may include, but is not limited to, the following processes. Top plugs are formed on the second sub-plurality of pillars in the same process for forming the top diffusion layers. The top plugs are electrically coupled to the second sub-plurality of pillars. The top plugs are made of a same material as the top diffusion layers.

In some cases, the method may include, but is not limited to, the following processes. Connection plugs are formed, which are electrically connected to the top plugs and the top diffusion layers. Top interconnects are formed, which are electrically connected to the connection plugs.

In some cases, forming the gate electrodes may include, but is not limited to, the following processes. A titanium nitride film is formed on the gate insulating film. The titanium nitride film is disposed in one side of the gate insulating film, while the first sub-plurality of pillar is disposed in the other side of the gate insulating film. A tungsten film is formed on the titanium nitride film. The tungsten film filling gaps are formed between the plurality of pillars.

In some cases, forming the gate electrodes may include, but is not limited to, the following processes. The gate electrode is formed, which surrounds each of the pillars.

In some cases, forming the contact plug may include, but is not limited to, the following processes. Before diffusing the impurity, an inter-layer insulating film is formed. First and second contact holes are formed in the inter-layer insulating film. The first and second contact holes expose the top plug and the top diffusion layer respectively. A resist film is formed over the inter-layer insulating film. The resist film fills the first and second contact holes. The resist film over the top plug is selectively removed to form an opening over the top plug.

### (Semiconductor Device)

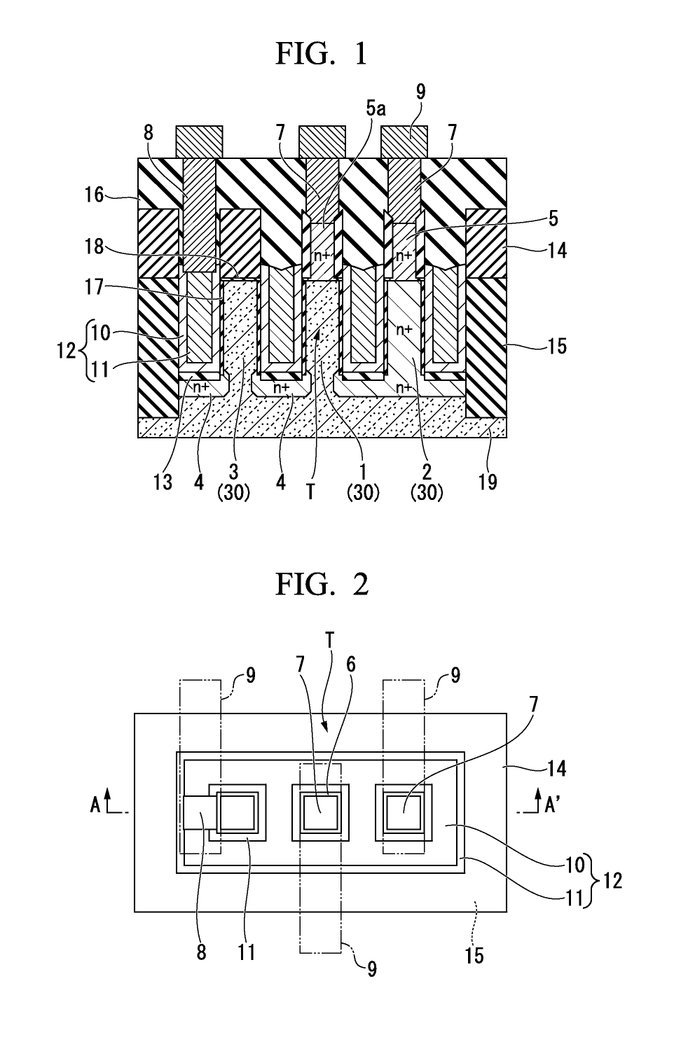

FIG. 1 is a cross-sectional view for describing an example of a semiconductor device of the present invention. FIG. 2 is a plan view of the semiconductor device shown in FIG. 1. The cross-sectional view shown in FIG. 1 is along the line A-A′ of FIG. 2.

In the present embodiment, the description is of an example of a semiconductor memory device (DRAM) as the semiconductor device of the present invention. FIG. 1 and FIG. 2 are simplified views of the part of the DRAM of the present embodiment, showing only a vertical transistor of the DRAM and the area in the vicinity thereof. The DRAM of the present embodiment has a memory cell region and a peripheral circuit region disposed in the periphery of the memory cell region. The vertical transistor shown in FIG. 1 and FIG. 2 is provided in the DRAM peripheral circuit region.

In FIG. 1 and FIG. 2, reference numeral 19 indicates a silicon substrate, and reference numeral 15 indicates an element separation insulating film which is buried in the silicon substrate 19 to a depth of approximately 300 nm. As shown in FIG. 2, the plan view shape of the element separation insulating film 15 is substantially a rectangular frame. As shown in FIGS. 1 and 2, a trench having a depth of approximately 100 nm, which is the F (the minimum processing dimension) width, provided in the silicon substrate 19, provides three pillars 30 that are disposed with a fixed spacing.

In the present embodiment, not only the spacing between the pillars 30, but also width of the pillars 30, and the spacing between the side surfaces of the pillars 30 and the inner wall surfaces of the element separation insulating film 15 are made F (the the minimum processing dimension). Although the present embodiment is described as a semiconductor device having an element separation insulating film 15 having a shape that is substantially a rectangular frame seen in plan view, and a spacing between the side surfaces of the pillars 30 and the inner wall surfaces of the element separation insulating film 15 being F (the minimum process dimension), there is no particular restriction regarding the plan view shape of the element separation insulating film.

As shown in FIG. 1, in the regions outside of the region in which the pillars 30 are provided within the element separation insulating film 15 when seen in plan view (stated differently, in the regions between adjacent pillars 30 and the region between the side surfaces of the pillars 30 and the inner wall surfaces of the element separation insulating film 15), a lower diffusion layer 4 is formed by the diffusion of an impurity that has a polarity (which is (n+) in the present embodiment) that is opposite that of the silicon substrate 19 (which is (p+) in the present embodiment). As shown in FIG. 1, the impurity having a polarity that is opposite that of the silicon substrate 19 diffuses also from the peripheral part of the bottom of each pillar 30 into part of the underneath of each pillar 30, and the lower diffusion layer 4 is connected to the lower part of each pillar 30. The lower diffusion layer 4 functions as one of the source/drain of the vertical transistor T.

The three pillars 30 shown in FIG. 1 and FIG. 2 include a channel pillar 1 made of a semiconductor layer disposed at the inside center part of the element separation insulating film 15, a lead contact plug 2 disposed to the right of the channel pillar 1 in FIG. 1 and FIG. 2, made of an impurity diffusion layer diffused with an impurity having a polarity that is the opposite that of the silicon substrate 19, and a gate contact pillar 3 made of a silicon substrate disposed to the left of the channel pillar 1 in FIG. 1 and FIG. 2.

The channel pillar 1 functions as the channel of the vertical transistor T. The vertical transistor T has an upper diffusion layer 5a connected to the top part of the channel pillar 1, and a gate electrode 12 disposed in opposition to the side surface of the channel pillar 1 via the gate electrode insulating film 17 made of an oxide film or the like.

The upper diffusion layer 5a functions as the other of the source/drain of the vertical transistor T, and has diffused therein an impurity having a polarity opposite that of the silicon substrate 19.

As shown in FIG. 1 and FIG. 2, the gate electrode 12 is formed by the film laminate of the titanium nitride film 10 and the tungsten film 11. The titanium nitride film 10 has a thickness of approximately 5 nm, and is disposed on the gate electrode insulating film 17 side of the tungsten film 11. The gate electrode 12, as shown in FIG. 1 and FIG. 2, is disposed so as to surround the entire side surface of each of the pillars 30, with an intervening gate electrode insulating film 17.

Although the material of the gate electrode 12 is not particularly restricted, and is preferably made of a material that has a high density, such as the laminate of a titanium nitride (density: 5.4 g/cm³) film 10 and a tungsten (density: 19 g/cm³) film 11, a different material, such as single-layer film such as that of polysilicon (density: 2.3 g/cm³) may be used.

If the gate electrode 12 is made of a material having a high density, such as a film laminate of the titanium nitride film 10 and the tungsten film 11, the gate electrode 12 has a superior effectiveness in blocking seeds to prevent the intrusion of an impurity into the channel pillar 1 that functions as the channel of the vertical transistor T when an impurity is ion-implanted into the pillars 30, which will serve as lead contact plugs 2. As a result, when ion implanting an impurity into the pillars 30 that serve as lead contact plugs 2, it is possible to effectively prevent the impurity from passing through the gate electrode 12 and entering the channel pillar 1 that functions as the channel of the vertical transistor T.

As shown in FIG. 1 and FIG. 2, above the gate electrode 12 disposed between the gate contact pillar 3 and the inner wall surface of the element separation insulating film 15, a gate contact plug 8 is provided that passes through an interlayer insulating film 16 that is made of an oxide film or the like. The gate contact plug 8 is made of a conducting material such as metal, and is electrically connected to an upper layer interconnect 9 provided at the top of the gate electrode 12 and the top of the interlayer insulating film 16.

As shown in FIG. 1 and FIG. 2, a pillar mask nitride film 14 provided for the purpose of forming a trench of a given shape for forming the pillar 30 is provided in the silicon substrate 19, above the gate contact pillar 3 and above the element separation insulating film 15. An oxide film 18 that is formed before the formation of the pillars 30 in the silicon substrate 19 is provided between the gate contact pillar 3 and the pillar mask nitride film 14.

As shown in FIG. 1 and FIG. 2, a lower oxide film 13 having a thickness of approximately 10 nm is formed at the bottom part of the trench between each of the pillars 30, and between the side surface of the pillar 30 and the inner wall surface of the element separation insulating film 15.

The lead contact plug 2 is electrically connected to the lower diffusion layer 4. An upper plug 5 made of the same material as the upper diffusion layer 5a is provided at the top part of the lead contact plug 2, and the lead contact plug 2 is electrically connected to the upper plug 5. The lower diffusion layer 4 and the upper plug 5 are therefore electrically connected via the lead contact plug 2.

As shown in FIG. 1 and FIG. 2, a connection plug 7 that passes through the interlayer insulating film 16 is provided at each upper plug 5 and the upper diffusion layer 5a. The connection plug 7 is made of a conducting material such as metal, and is electrically connected to the upper layer interconnect 9 provided at the top of each interlayer insulating film 16. By doing this, the above the upper plug 5 and the upper diffusion layer 5a are electrically connected to the upper layer interconnect 9 via each of the connection plugs 7.

### (Method for Manufacturing a Semiconductor Device)

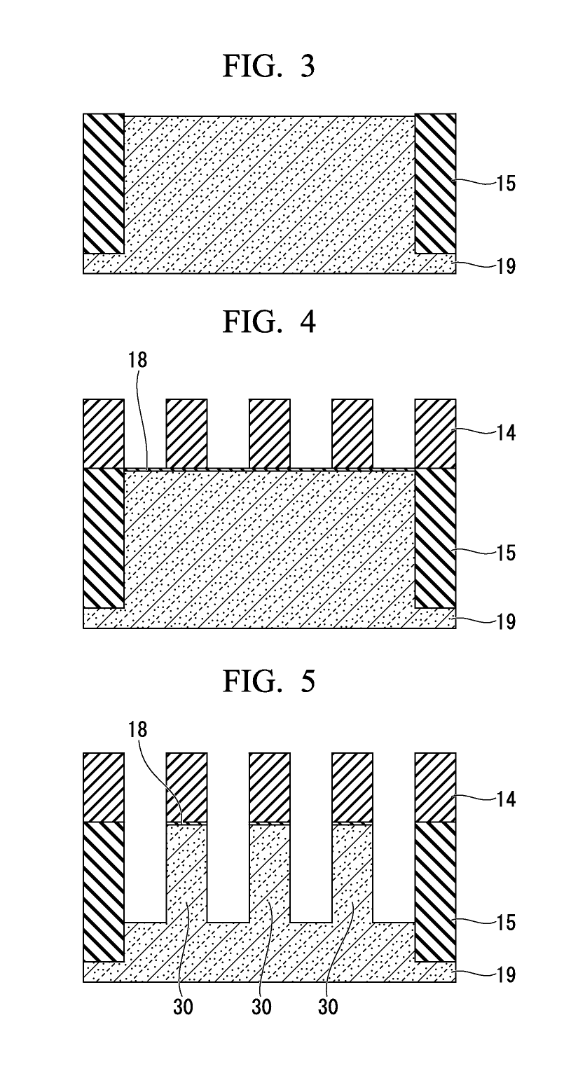

As an example of a method for manufacturing a semiconductor device of the present invention, the method for manufacturing the semiconductor device as shown in FIG. 1 and FIG. 2 will be described using the drawings. FIG. 3 to FIG. 11 are cross-sectional views for describing one process of the method for manufacturing the semiconductor device shown in FIG. 1 and FIG. 2.

In order to manufacture the semiconductor device shown in FIG. 1, first, as shown in FIG. 3, an element separation insulating film 15 is formed on a silicon substrate 19.

As shown in FIG. 4, an oxide film 18 is formed by thermal oxidation or the like over the surface of the silicon substrate 19 in which the element separation insulating film 15 is formed. Then, a pillar mask nitride film 14 that has a given pattern shape corresponding to the plan view shape of the pillar 30 is formed by dry etching with photoresist used as a mask over the oxide film 18 and the element separation insulating film 15.

dry etching is done with the pillar mask nitride film 14 used as a mask, thereby forming a trench into the silicon substrate 19, as shown in FIG. 5, three pillars 30 that are made from the semiconductor layer disposed with a spacing of F (the minimum processing dimension) being formed.

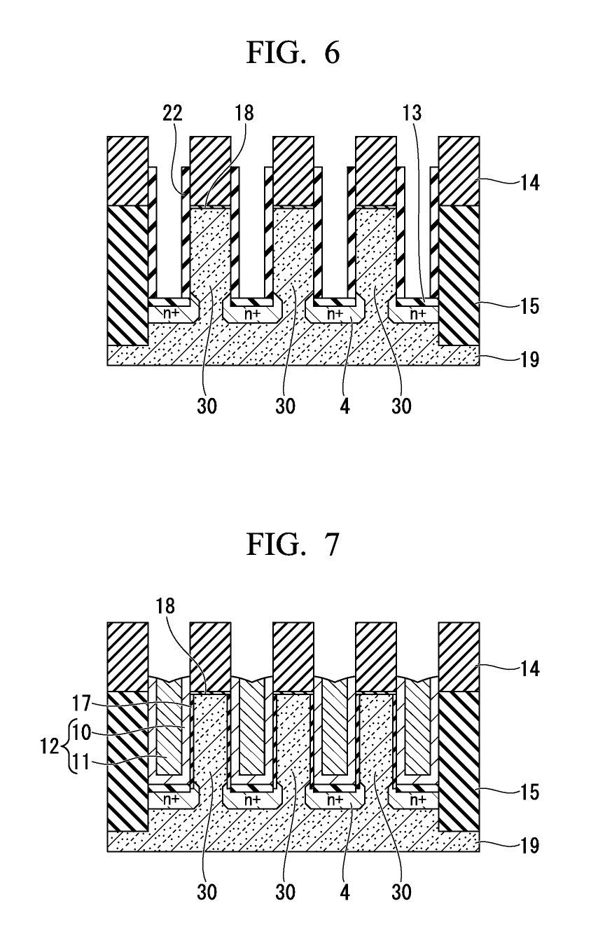

Using low-pressure chemical vapor deposition (LP-CVD), a nitride film is formed over the entire surface of the silicon substrate 19 forming the pillar 30, and then by performing etching back, as shown in FIG. 6, nitride films 22 are formed along inner walls of the trenches between the pillars 30, and between the side surface of pillars 30 and the inner wall surface of the element separation insulating film 15. By doing this, the nitride films 22 are formed so as to surround the entire side surface of pillars 30.

As shown in FIG. 6, by thermal oxidation lower oxide films 13 are formed at the bottoms of trenches between pillars 30, and between the side surface of pillars 30 and the inner wall surface of the element separation insulating film 15.

Then, an impurity having a polarity that is opposite that of the silicon substrate 19 (which is (n+) in the present embodiment) is introduced into the regions outside of the region in which the pillars 30 are provided within the element separation insulating film 15 when seen in plan view (that is the bottoms of trenches between the pillars 30 and between the side surfaces of the pillars 30 and the inner wall surfaces of the element separation insulating film 15) by ion implantation, so as to form lower diffusion layers 4 functioning as one of the source/drain of the vertical transistor T.

After doing this, the nitride films 22 are removed using hot phosphoric acid.

As shown in FIG. 7, gate oxide films 17 are formed so as to surround the entire side surface of pillars 30.

A titanium nitride film 10 having a thickness of approximately 5 nm is formed on the entire surface of the silicon substrate 19 in which the gate oxide film 17 is formed. By doing this, a titanium nitride film 10 disposed in opposition to the side surface of the pillar 30 is formed, with the gate insulating film 17 interposed therebetween.

A tungsten film 11 is laminated over the titanium nitride film 10 and the tungsten film 11 is buried into the trenches between the pillars 30, on the side surfaces of which the gate insulating film 17 and the titanium nitride film 10 are formed, and between the side surface of the pillar 30 and the inner wall surface of the element separation insulating film 15.

Then, the tungsten film 11 and the titanium nitride film 10 are sequentially etched back. By doing this, as shown in FIG. 7, a gate electrode 12 is formed so as to surround the entire side surface of the pillars 30, with the gate insulating film 17 interposed therebetween.

Using high-density plasma chemical vapor deposition (HDP-CVD) an oxide film is grown over the entire surface of the silicon substrate 19 on which the gate electrode 12 is formed, and then the oxide film that is a part of the interlayer insulating film 16 shown in FIG. 1 is buried between the pillar mask nitride films 14. Next, the chemical mechanical polishing (CMP) is done using the pillar mask nitride film 14 as stopper so that the oxide film is caused to plane.

After doing this, an oxide film having a thickness of approximately 10 nm, which is to be a part of the interlayer insulating film 16 shown in FIG. 1, is deposed again over the entire surface of planed oxide film and the pillar mask nitride film 14.

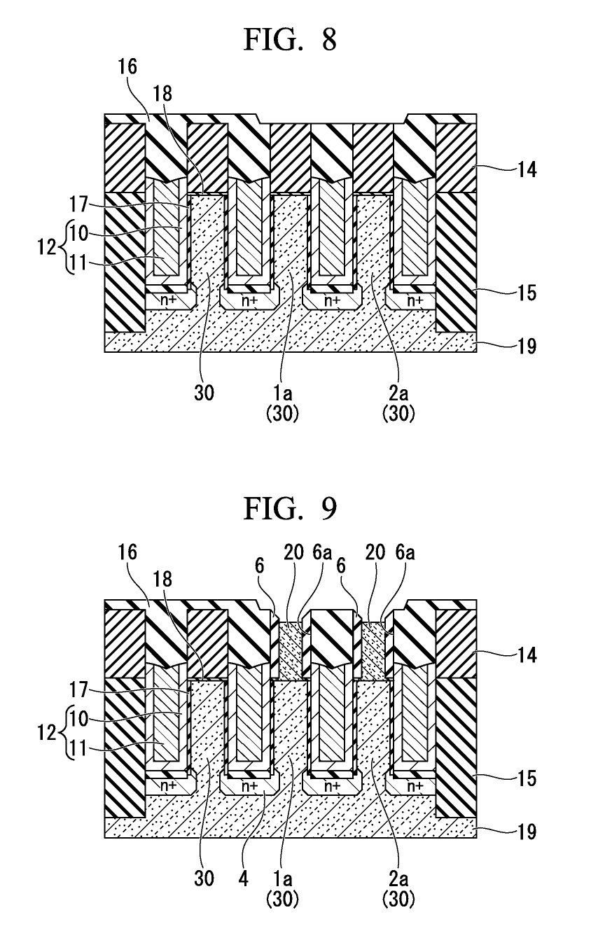

of pillars 30, only oxide film, which is disposed on the upper part of pillar la that serves as a channel pillar 1 that functions as a channel of the vertical transistor T, on the upper part of pillar 2a that serves as a lead contact plug 2 on which an impurity having a polarity that is opposite that of the silicon substrate 19 is diffused, and in the region between the pillar 1a and the pillar 2a seen in plan view, is dry-etched using photoresist as a mask up until the position of the upper surface of the pillar mask nitride film 14, thereby exposing the pillar mask nitride film 14 as shown in FIG. 8.

The pillar mask nitride films 14 exposed over the pillar 1a and pillar 2a are removed by hot phosphoric acid. By doing this, the contact hole 6a made of oxide film of which side surface constitutes the interlayer insulating film 16 is formed.

Using LP-CVD, a nitride film is formed over the entire surface of the silicon substrate 19 formed the contact hole 6a, and then by performing etching back, as shown in FIG. 9, side-wall (SW) nitride films 6 are formed on the side surface of the contact hole 6a.

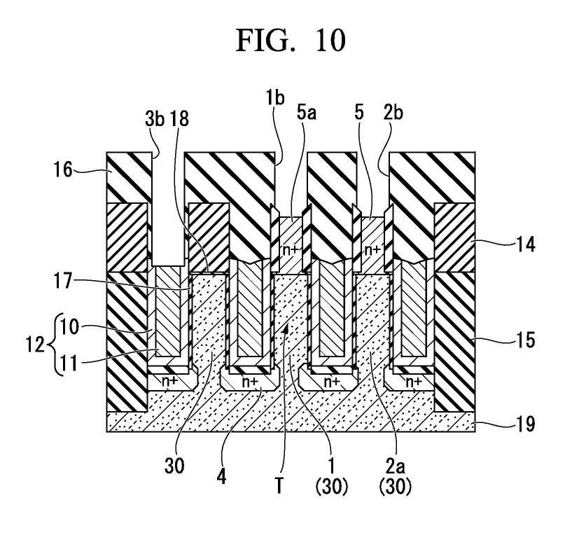

The oxide film 18 that is exposed within the contact hole 6a is removed, and selective-epitaxial growth is done, as shown in FIG. 9, to form epitaxial silicon 20 within the contact hole 6a. After doing this, an impurity having a polarity that is opposite that of the silicon substrate 19 is introduced into the epitaxial silicon 20 by ion implantation. By doing this, as shown in FIG. 10, an upper diffusion layer 5a functioning as other of the source/drain of the vertical transistor T if formed over the upper part of the pillar 1a, and simultaneously, the upper plug 5 made of the same material as the upper diffusion layer 5a is formed on the upper part of pillar 2a that is not used as the channel pillar 1 among a plurality of pillars 30.

According to the above-noted process step, the channel pillar 1 that functions as a channel using part of pillars la of a plurality of pillars 30 is formed, and the vertical transistor T, which has the channel pillar 1, the lower diffusion layer 4 connected to the lower part of the channel pillar 1, the upper diffusion layer 5a connected to the upper part of the channel pillar 1, and the gate electrode 12 disposed in opposition to a side surface of the channel pillar 1 via a gate insulating film 17, is formed.

An oxide film which will serve as part of the interlayer insulating film 16 is grown over the entire surface on the top of the silicon substrate 19 formed the upper diffusion layer 5a and the upper plug 5. Then, the oxide film is selectively removed as shown in FIG. 10, so as to form contact holes 1b, 2b and 3b, which respectively expose above the upper diffusion layer 5a, the upper plug 5, and above the gate electrode 12 disposed between the pillar 30 that serves as the gate contact pillar 3 and the inner wall surface of the element separation insulating film 15.

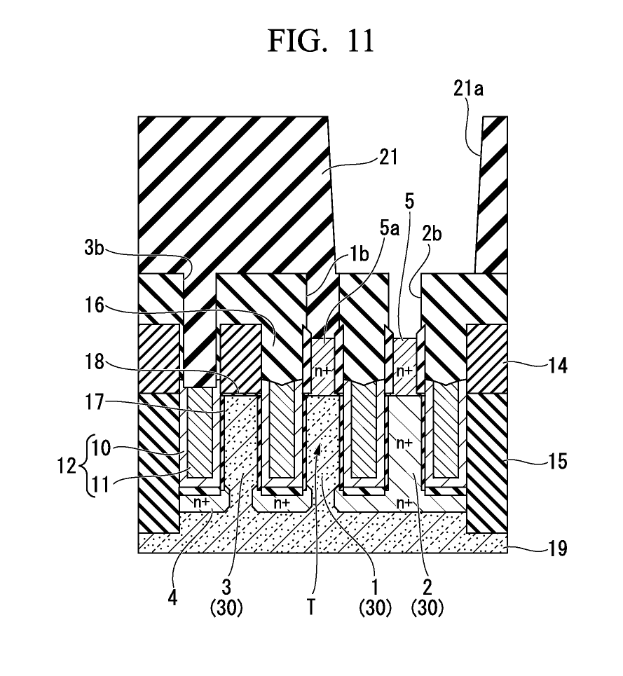

A resist layer 21 is formed over the entire surface at the top of the interlayer insulating film 16 having a contact hole (second contact hole) 1b in which the upper diffusion layer 5a is exposed at the bottom surface, a contact hole (first contact hole) 2b in which the upper plug 5 is exposed at the bottom surface, and a contact hole 3b in which the gate electrode 12 is exposed at the bottom surface, so as to bury the resist layer 21 into the contact holes 1b, 2b, and 3b. After doing this, as shown in FIG. 11, the resist layer 21 on the upper plug 5 is selectively removed so as to form an aperture 21a. By doing this, the upper plug 5 is exposed again within the contact hole 2b.

Also, in the present embodiment, when the resist layer 21 above the upper plug 5 is selectively removed, when seen in plan view, the resist layer 21 disposed in the peripheral region of the contact hole 2b above the upper plug 5 is also removed. At the bottom surface of the aperture 21a, the contact hole 2b above the upper plug 5 and the interlayer insulating film 16 disposed in the peripheral region are then exposed.

An impurity having a polarity that is opposite that of the silicon substrate 19 is diffused to the pillar 2a disposed below the upper plug 5 by ion implantation, so as to impart a low resistance to the pillar 2a. By doing this, the lead contact plug 2 electrically connected to the upper plug 5 and the lower diffusion layer 4, which are made of a diffusion layer having the same type of polar, is formed.

Before diffusing an impurity to the pillar 2a that serves as the lead contact plug 2, in order to form the lead contact plug 2, the present embodiment includes a process step to form the interlayer insulating film 16 having the contact hole 2b in which the upper plug 5 is exposed at the bottom surface and the contact hole 1b in which the upper diffusion layer 5a is exposed at the bottom surface, and a process step to form a resist layer over the interlayer insulating film 16 so as to bury the contact holes 1b and 2b and to form the aperture 21a by selectively removing the resist layer 21 over the upper plug 5, so that, as shown below, in the process step to diffuse the impurity to the pillar 2a that serves as the lead contact plug 2, it is possible to effectively prevent the impurity from entering into the channel pillar 1 that functions as the channel of the vertical transistor T.

As the spacing between the pillar 2a that serves as the lead contact plug 2 and the channel pillar 1 functioning as the channel is made narrow for the purpose of reducing the mounting surface area for the vertical transistor, the channel pillar 1 is covered over, making it difficult to form the resist layer 21 having an aperture 21a above the pillar 2a that serves as the lead contact plug 2.

As in the method for manufacturing the present embodiment, however, in the case in which the interlayer insulating film 16 having the contact holes 1b and 2b is formed on the channel pillar 1 and on the lead contact plug 2 before forming the resist layer 21 having the aperture 21a, the formation of resist layer 21 buries the resist layer 21 into the contact hole 1b in the channel pillar 1.

Compared to the resist layer 21 buried within the contact hole 1b in the channel pillar 1 with the resist layer 21 formed on the interlayer insulating film 16, the thickness of film is larger and also the shape makes removal difficult. Therefore, even if, for example, a part or all of the upper edge of the contact hole 1b over the channel pillar 1 (refer, for example, to FIG. 11) is exposed at the bottom surface of the aperture 21a of the resist layer 21, the resist layer 21 within the contact hole 1b over the channel pillar 1 and the interlayer insulating film 16 forming the outer periphery of the contact hole 1b can prevent the impurity diffusing into the pillar 2a that serves as the lead contact plug 2 from entering into the channel pillar 1.

When the aperture 21a that exposes the top of the pillar 2a that serves as the lead contact plug 2 is formed in the resist layer 21 used as a mask when an impurity is caused to diffuse into the pillar 2a that serves as the lead contact plug 2, the spacing between the pillar 2a that serves as the lead contact plug 2 and the channel pillar 1 functioning as a channel can be determined regardless of whether or not the aperture 21a can be formed in a manner in which the region seen in plan view as overlapping with the cannel pillar 1 is not exposed within the aperture 21a.

As the result of the above, it is possible to impart an allowance of margin in the pattern shape used in lithography to form the aperture 21a of the resist layer 21 and, without interfering with the channel pillar 1 functioning as the channel, it is possible to easily make the spacing between the pillar 2a that serves as the lead contact plug 2 and the channel pillar 1 functioning as a channel to F (the minimum process dimension) narrow. Thus, according to the present embodiment, it is possible to easily form a semiconductor device suitable for achieving a high level of integration and having an adjacent spacing of F (the minimum process dimension) between the lead contact plug 2 and the channel pillar 1.

The resist layer 21 is removed, and a conductive material is buried into the contact holes 1b, 2b and 3b. By doing this, the connection plug 7 for electrically connecting to each of the upper plug 5, the upper diffusion layer 5a, and the upper layer interconnect 9, is formed. Also, the gate contact plug 8 for electrically connecting to the gate electrode 12 and the upper layer interconnect 9 is formed in the contact hole 3b.

After doing this, the upper layer interconnect 9 connected to the top of the upper layer interconnect 9 and gate contact plug 8 respectively is formed.

According to the above process, the semiconductor device as shown in FIG. 1 is obtained.

Because a semiconductor device of the present embodiment includes a plurality of pillars 30 disposed with a given spacing, in which the plurality of pillars 30 includes a channel pillar 1 having a semiconductor layer that functions as a channel of a vertical transistor T and the lead contact plug 2 made of an impurity diffusion layer and connected to the lower portion of the channel pillar 1 and electrically connected to an lower diffusion layer 4 functioning as one of the source/drain of the vertical transistor T, the spacing between the channel pillar 1 and the lower diffusion layer lead contact plug 2 is the same as the spacing between other pillars.

In the present embodiment, because the spacing between the pillars 30 is F (the minimum process dimension), the spacing between the channel pillar 1 and the lower diffusion layer lead contact plug 2 is F (the minimum process dimension). The semiconductor device of the present embodiment thus has a small mounting surface area for the vertical transistor T, so as to be suitable for a high level of integration.

Furthermore, in the semiconductor device of the present embodiment, there is no decrease of the transistor on-state current due to a long channel length as is the case when a vertical transistor is connected in series, and it is possible to achieve a high level of integration of the vertical transistor T without worsening the characteristics of transistor.

Also, in the present embodiment, an upper plug 5 made of the same material as an upper diffusion layer 5a is provided at the top of the lead contact plug 2, and the lead contact plug 2 is electrically connected to the upper plug 5. Therefore, using the lead contact plug 2 and the upper plug 5, it is possible within a small surface area to electrically connect to the lower diffusion layer 4 and an upper layer interconnect 9 provided over an interlayer insulating film 16.

Furthermore, in the present embodiment, because connection plugs 7 electrically connecting to upper layer interconnects 9 are provided over the upper plug 5 and the upper diffusion layer 5a, via the lead contact plug 2, the upper plug 5, and the connection plug 7, it is possible to electrically connect to the lower diffusion layer 4 and the upper layer interconnect 9 provided over the interlayer insulating film 16, within a small surface area.

Also, the method for manufacturing a semiconductor device of the present embodiment includes a step of forming a plurality of pillars 30 disposed with a given spacing; a step of forming a lower diffusion layer 4 connected to a lower part of the pillar 30 and functioning as one of the source/drain of the vertical transistor T; a step of forming a channel pillar 1 made of a semiconductor layer that functions as the channel of the vertical transistor T, using a part of pillars la of a plurality of pillars 30; and a step of forming the lead contact plug 2 that electrically connects with the lower diffusion layer 4 by diffusing an impurity to a part of pillars 2a that is not used for the channel pillar 1 of a plurality of pillars 30. It is therefore possible to manufacture the semiconductor device of the present embodiment that has a plurality of pillars 30 that includes the channel pillar 1 of the vertical transistor T and the lead contact plug 2.

Also, because a method for manufacturing a semiconductor device of the present embodiment, in the step of forming a plurality of pillars 30, because a pillar 30 which will serve as the channel pillar 1 of the vertical transistor T and a pillar 30 which will serve as the lead contact plug 2 are formed simultaneously, compared with, for example, the case in which a pillar that serves as a channel pillar of the vertical transistor T and a lead contact plug are formed separately, it is possible to narrow the spacing between the channel pillar 1 and the lower diffusion layer lead contact plug 2 and to effectively manufacture with fewer manufacturing process steps.

Also, in a method for manufacturing a semiconductor device of the present embodiment, a step for forming the upper diffusion layer 5a forms the upper diffusion layer 5a, and simultaneously forms the upper plug 5 made of the same material as the upper diffusion layer 5a and electrically connects to the lead contact plug 2 over the pillar 2a that serves as the lead contact plug 2. Therefore, it is possible to form the upper plug 5 used for electrical connection between the lead contact plug 2 and the upper layer interconnect 9, without the need to provide a process step for forming the upper plug 5.

Also, in the method for manufacturing a semiconductor device of the present embodiment the connection plugs 7 electrically connecting to the upper layer interconnects 9 are formed over the upper plug 5 and over the upper diffusion layer 5a respectively. For that reason, a process step of forming the interlayer insulating film 16 that has a contact hole 2b exposing the upper plug 5 on the bottom surface and that has a contact hole 1b exposing the upper diffusion layer 5a on the bottom surface, and a process step of forming the resist layer over the interlayer insulating film 16 so as to bury the contact holes 1b and 2b and removing selectively the resist layer 21 over the upper plug 5 so as to form an aperture 21a are performed, after which an impurity is diffused into the pillar 2a that serves as the lead contact plug 2. As a result, as described above, it is possible to easily narrow the spacing between the pillar 2a that serves as the lead contact plug 2 and the channel pillar 1 that functions as the channel to F (the minimum process dimension), without interfering with the channel pillar 1 that functions a channel.

Also, in the method for manufacturing a semiconductor device of the present embodiment, although the upper plug 5 and the upper diffusion layer 5a are formed, and then an impurity is diffused on the pillar 2a that serves as the lead contact plug 2, the impurity may be diffused on the pillar 2a that serves as the lead contact plug 2 before forming the upper plug 5 and the upper diffusion layer 5a. The semiconductor device of the present embodiment having a plurality of pillars 30 that includes the channel pillar 1 of the vertical transistor T and the lead contact plug 2 can be manufactured in this case as well.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

Furthermore, the particular features, structures, or characteristics may be combined in any suitable manner in one or more embodiments.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A semiconductor device comprising:
a transistor comprising: a semiconductor channel pillar having a vertical channel; and a first diffusion region adjacent to a lower portion of the semiconductor channel pillar; and
a contact plug pillar of an impurity-diffused semiconductor coupled to the first diffusion region.

2. The semiconductor device according to claim 1, wherein the first diffusion region and the contact plug pillar are higher in impurity concentration than the semiconductor channel pillar.

3. The semiconductor device according to claim 2, wherein the vertical transistor further comprises:
a second diffusion region disposed on a top of the semiconductor channel pillar.

4. The semiconductor device according to claim 3, wherein the vertical transistor further comprises:
a gate insulating film covering a side wall surface of the semiconductor channel pillar; and
a gate electrode on the gate insulating film, the gate electrode having a first side surface that faces toward the semiconductor channel pillar through the gate insulating film.

5. The semiconductor device according to claim 4, wherein the gate electrode is disposed at least a gap between the semiconductor channel pillar and the contact plug pillar.

6. The semiconductor device according to claim 5, wherein the gate electrode and the gate insulating film surround the semiconductor channel pillar and the gate electrode and the gate insulating film also surround the contact plug pillar.

7. The semiconductor device according to claim 5, wherein the gate electrode comprises:
a tungsten film; and
a titanium nitride film disposed between the tungsten film and the gate insulating film.

8. The semiconductor device according to claim 5, further comprising:
a first insulating film extending between the gate electrode and the contact plug pillar.

9. The semiconductor device according to claim 5, further comprising:
a top plug disposed on a top of the contact plug pillar, the top plug being made of a same material as the second diffusion region, the top plug being coupled to the contact plug pillar.

10. The semiconductor device according to claim 9, further comprising:
a first connection plug disposed on the second diffusion region;
a second connection plug disposed on the top plug;
a first interconnect coupled through the first connection plug to the second diffusion region; and
a second interconnect coupled through the second connection plug to the top plug.

11. The semiconductor device according to claim 1, wherein the contact plug pillar is substantially the same in top level as the semiconductor channel pillar.

12. The semiconductor device according to claim 4, wherein the contact plug pillar and the semiconductor channel pillar are lower in top level than the gate electrode.

13. The semiconductor device according to claim 1, wherein the contact plug pillar has substantially the same in impurity concentration as the first diffusion region.

14. The semiconductor device according to claim 4, wherein the contact plug pillar and the semiconductor channel pillar are substantially the same horizontal dimensions as each other.

15. A semiconductor device comprising:
a semiconductor substrate;
a first semiconductor pillar extending from the substrate, the first semiconductor pillar being substantially the same in impurity concentration as the semiconductor substrate; and
a second semiconductor pillar extending from the substrate, the second semiconductor pillar being spatially separated from the first semiconductor pillar, the second semiconductor pillar being higher in impurity concentration than the semiconductor substrate and the first semiconductor pillar.

16. The semiconductor device according to claim 15, further comprising:
a bottom diffusion region in the semiconductor substrate, the bottom diffusion region being adjacent to a bottom of the first semiconductor pillar, the bottom diffusion region being coupled to the second semiconductor pillar, and
wherein the second semiconductor pillar comprises a diffusion region coupled to the bottom diffusion region.

17. The semiconductor device according to claim 16, further comprising:
a first top diffusion region on a top of the first semiconductor pillar;
a gate insulating film covering side wall surfaces of the first semiconductor pillar;
a gate electrode disposed in the gap between the first and second semiconductor pillars; and
a first insulating film covering side wall surfaces of the second semiconductor pillar,
wherein the gate electrode is separated by the gate insulating film from the first semiconductor pillar, and the gate electrode is separated by the first insulating film from the second semiconductor pillar.

18. The semiconductor device according to claim 17, wherein the first and second semiconductor pillars have substantially the same height as each other, and
the first and second semiconductor pillars are lower in top level than the gate electrode.

19. The semiconductor device according to claim 18, further comprising:
a second top diffusion region on a top of the second semiconductor pillar, the second top diffusion region being made of a same material as the first top diffusion region, the second top diffusion region being coupled to the second semiconductor pillar;
a first connection plug disposed on the first top diffusion region;
a second connection plug disposed on the second top diffusion region;
a first interconnect coupled through the first connection plug to the first top diffusion region; and
a second interconnect coupled through the second connection plug to the second top diffusion region.

20. A semiconductor device comprising:
a semiconductor substrate;
a semiconductor channel pillar having a vertical channel, the semiconductor channel pillar extending from the semiconductor substrate;
a contact plug pillar extending from the semiconductor substrate, the contact plug pillar being spatially separated from the semiconductor channel pillar;
a semiconductor diffusion region being higher in impurity concentration than the semiconductor substrate and the semiconductor channel pillar, the semiconductor diffusion region occupying the contact plug pillar and a shallow region of the semiconductor substrate, the shallow region being adjacent to a bottom of the semiconductor channel pillar;
a gate electrode between the semiconductor channel pillar and the contact plug pillar; and
an insulating film between the semiconductor channel pillar and the contact plug pillar, the insulating film electrically insulating the gate electrode from the semiconductor channel pillar and from the contact plug pillar.
